(19) United States
(12) Patent Application Publication
(10) Pub. No.: US 2026/0068032 A1
(43) Pub. Date: Mar. 5, 2026

(54) PRINTED CIRCUIT BOARD, BATTERY PACK, AND METHOD OF MANUFACTURING PRINTED CIRCUIT BOARD

(71) Applicant: Samsung SDI Co., Ltd., Yongin-si (KR)

(72) Inventor: Tae Jin Lee, Yongin-si (KR)

(73) Assignee: Samsung SDI Co., Ltd., Yongin-si (KR)

(21) Appl. No.: 19/309,927

(22) Filed: Aug. 26, 2025

(30) Foreign Application Priority Data
Aug. 27, 2024 (KR) 10-2024-0115421

(51) Int. Cl. H05K 1/02; H01M 10/52; H01M 50/176; H01M 50/179; H01M 50/284

(52) U.S. Cl. CPC H05K 1/0209; H01M 10/52; H01M 50/176; H01M 50/179; H01M 50/284; H05K 2201/068; H05K 2201/10166; H05K 2201/10181

(57) ABSTRACT

Disclosed are a printed circuit board, a battery pack, and a method of manufacturing a printed circuit board. The printed circuit board may include a substrate, a large current stage part disposed in a mounting area of the substrate, and a coating layer including phase change materials (PCMs) and covering the large current stage part.

### CROSS-REFERENCE TO RELATED APPLICATIONS

This present application claims priority to and the benefit under 35 U.S.C. § 119 (a)-(d) of Korean Patent Application No. 10-2024-0115421, filed on Aug. 27, 2024, in the Korean Intellectual Property Office, the entire disclosure of which is incorporated herein by reference.

### FIELD

The present disclosure relates to a printed circuit board, a battery pack, and a method of manufacturing a printed circuit board, and to a printed circuit board, a battery pack, and a method of manufacturing a printed circuit board, wherein a coating layer including phase change materials (PCMs) is formed.

### BACKGROUND

Unlike primary batteries that are not designed to be charged, secondary batteries are designed to be discharged and recharged. Low-capacity secondary batteries are used in small portable electronic devices, such as smart phones, feature phones, notebook computers, digital cameras, and camcorders, while large-capacity secondary batteries are widely used as power sources for driving motors, such as of hybrid vehicles or electric vehicles, and for power storage. The secondary battery includes an electrode assembly consisting of a positive electrode and a negative electrode, a case that accommodates the electrode assembly, a terminal part connected to the electrode assembly, etc.

If a battery pack constructed by using a secondary battery is used outdoors, waterproof processing is performed on the battery pack. A printed circuit board including a battery management system (BMS) is mounted on a battery cell. If water infiltrates into the printed circuit board, waterproof processing also needs to be performed on the printed circuit board because the printed circuit board may fail due to a short circuit. Conventionally, silicon is coated on a part of the printed circuit board for the waterproofness of the printed circuit board. However, if silicon is coated on the entire substrate, there is a problem in that heat from a heating part is not properly discharged.

The above information disclosed in this Background section is for enhancement of understanding of the background of the present disclosure, and therefore, it may contain information that does not constitute related (or prior) art.

### SUMMARY

Embodiments provide a printed circuit board, a battery pack, and a method of manufacturing a printed circuit board, wherein a coating layer including phase change materials (PCMs) is formed.

However, the technical problem to be solved by the present disclosure is not limited to the above problem, and other problems not mentioned herein, and aspects and features of the present disclosure that would address such problems, will be clearly understood by those skilled in the art from the description of the present disclosure below.

A printed circuit board according to embodiments of the present disclosure may include a substrate, a large current stage part disposed in a mounting area of the substrate, and a coating layer including phase change materials (PCMs) and covering the large current stage part.

In embodiments, the large current stage part may include one or more of an SR latch, a field effect transistor (FET), and a fuse.

In embodiments, the coating layer may be formed by coating with a coating solution including the PCMs and silicon.

In embodiments, the PCMs may include capsulated paraffin wax.

In embodiments, the coating layer may have a thickness of 1 cm to 1.5 cm.

In embodiments, the coating layer may be formed not to cover a metal tab formed in a part of the outskirts of the substrate.

In embodiments, the coating layer may be formed so that the coating solution that forms the coating layer does not flow into the metal tab by covering with a guide bar the outskirts of the substrate including the metal tab.

A battery pack according to embodiments of the present disclosure may include a plurality of battery cells, a case on which the plurality of battery cells is mounted, and a printed circuit board connected to the plurality of battery cells and the case. The printed circuit board may include a substrate, a large current stage part disposed in a mounting area of the substrate, and a coating layer that covers the large current stage part.

In embodiments, the large current stage part may include one or more of an SR latch, a field effect transistor (FET), and a fuse.

In embodiments, the coating layer may be formed by coating with a coating solution including the PCMs and silicon.

In embodiments, the PCMs may include capsulated paraffin wax.

In embodiments, the coating layer may have a thickness of 1 cm to 1.5 cm.

In embodiments, the coating layer may be formed not to cover a metal tab formed in a part of the outskirts of the substrate.

In embodiments, the coating layer may be formed so that the coating solution that forms the coating layer does not flow into the metal tab by covering the outskirts of the substrate including the metal tab with a guide bar.

A method of manufacturing a printed circuit board according to embodiments of the present disclosure may include providing a substrate, disposing a large current stage part in a mounting area of the substrate, and forming a coating layer including phase change materials (PCMs) so that the coating layer covers the large current stage part.

The disposing of the large current stage part may include disposing the large current stage part including one or more of an SR latch, a field effect transistor (FET), and a fuse in the mounting area of the substrate.

The forming of the coating layer may include forming the coating layer by coating with a coating solution including the PCMs and silicon.

The forming of the coating layer may include forming the coating layer so that the coating layer may have a thickness of 1 cm to 1.5 cm.

The forming of the coating layer may include forming the coating layer so that the coating layer does not cover a metal tab formed in a part of the outskirts of the substrate. The forming of the coating layer so that the coating layer does not cover the metal tab may include covering with a guide bar the outskirts of the substrate including the metal tab, flowing a coating solution that forms the coating layer on the substrate so that the coating solution does not flow into the metal tab, forming the coating layer by hardening the coating solution, and removing the guide bar.

According to embodiments of the present disclosure, a waterproof effect can be achieved and heat that is generated from a heating part can also be effectively discharged by forming the coating layer including the phase change materials (PCMs).

According to embodiments of the present disclosure, the printed circuit board can be cooled and the size of the printed circuit board can be minimized by generally covering a heating part without the need to open a part of the heating part because the coating layer including the PCMs is generally formed on the printed circuit board.

According to embodiments of the present disclosure, costs can be reduced compared to a circumstance in which only the PCMs is used because the coating solution is manufactured by mixing silicon with the capsulated PCMs potting agent.

According to embodiments of the present disclosure, it is possible to prevent the coating solution from flowing into the outskirts of the substrate because the coating layer is formed by covering the guide bar at the outskirts of the substrate.

However, aspects and features of the present disclosure are not limited to those described above, and other aspects and features not mentioned will be clearly understood by a person skilled in the art from the detailed description, described below.

### BRIEF DESCRIPTION OF THE DRAWINGS

The following drawings attached to this specification illustrate preferred embodiments of the present disclosure, and help to further understand the technical spirit of the present disclosure along with the aforementioned contents of the disclosure. Accordingly, the present disclosure should not be construed as being limited to only contents described in such drawings:

FIG. 1A is a top perspective view of a cylindrical secondary battery.

FIG. 1B is a cross-sectional view of a cylindrical secondary battery.

FIG. 2A is a top perspective view of a prismatic secondary battery.

FIG. 2B is a cross-sectional view taken along line I-I′ in FIG. 2A.

FIG. 3 is a perspective view of a battery pack including a printed circuit board according to embodiments of the present disclosure.

FIG. 4 is a plan view of the printed circuit board according to embodiments of the present disclosure.

FIG. 5 is a diagram illustrating a form before a guide bar is applied to the printed circuit board according to embodiments of the present disclosure.

FIG. 6 is a diagram illustrating a form after the guide bar is applied to the printed circuit board according to embodiments of the present disclosure.

FIG. 7 is a flowchart for describing a method of manufacturing a printed circuit board according to embodiments of the present disclosure.

### DETAILED DESCRIPTION

Exemplary embodiments of the present disclosure will be described below in detail with reference to the accompanying drawings. Prior to the description, it is noted that the terms or words used in this specification and claims should not be construed as being limited to common or dictionary meanings but instead should be understood to have meanings and concepts in agreement with the spirit of the present disclosure based on the principle that an inventor can define the concept of each term suitably in order to describe his/her own invention in the best way possible. Accordingly, since the embodiments described in this specification and the configurations illustrated in the drawings are only an example of the present disclosure and they do not cover all the technical ideas of the present disclosure, it should be understood that various changes and modifications may be made at the time of filing this application.

It will be further understood that the terms “comprises/includes” and/or “comprising/including” when used herein, specify the presence of stated features, integers, steps, operations, elements, components, and/or groups thereof, but do not preclude the presence or addition of one or more other features, integers, steps, operations, elements, components, and/or groups thereof.

In order to facilitate understanding of the present disclosure, the accompanying drawings are not drawn to scale and the dimensions of some components may be exaggerated. It should be noted that the same reference numerals are designated to the same components in different embodiments. Reference to two compared elements, features, etc. as being “the same” means that they are “substantially the same”. Therefore, the phrase “substantially the same” may include a deviation that is considered low in the art, for example, a deviation of 5% or less. The uniformity of any parameter in a given region may mean that it is uniform from an average perspective.

Although the terms such as “first” and/or “second” are used to describe various components, these components are not limited by these terms, of course. These terms are only used to distinguish one component from another component. Thus, unless specifically stated to the contrary, a first component may be termed a second component without departing from the teachings of exemplary embodiments.

Throughout the specification, unless otherwise stated, each element may be singular or plural.

Arrangement of any component “above (or below)” or “on (or under)” a component may mean that any component is disposed in contact with the upper (or lower) surface of the component, as well as that other components may be interposed between the element and any element disposed on (or under) the element.

It will be understood that, when a component is referred to as being “connected”, “coupled”, or “joined” to another component, not only can it be directly “connected”, “coupled”, or “joined” to the other element, but also can it be indirectly “connected”, “coupled”, or “joined” to the other element with other elements interposed therebetween. As used herein, the term “and/or” includes any and all combinations of one or more of the associate listed items. The use of “may” when describing embodiments of the present disclosure relates to “one or more embodiments of the present disclosure”. Expressions such as “at least one” and “one or more” preceding a list of elements modify the entire list of elements and do not modify the individual elements in the list.

Throughout the specification, when “A and/or B” is stated, it means A, B, or A and B, unless otherwise stated. In addition, when “C to D” is stated, it means C or more and D or less, unless specifically stated to the contrary.

When the phrase such as “at least one of A, B, and C”, “at least one of A, B, or C”, “at least one selected from the group of A, B, and C”, or “at least one selected from among A, B, and C” is used to designate a list of elements A, B, and C, the phrase may refer to any and all suitable combinations.

The term “use” may be considered synonymous with the term “utilize”. As used herein, the terms “substantially,” “about,” and similar terms are used as terms of approximation rather than as terms of degree, and are intended to account for inherent variations in measured or calculated values that would be recognized by those of ordinary skill in the art. It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Accordingly, a first element, component, region, layer, or section discussed below may be termed a second element, component, region, layer, or section without departing from the teachings of exemplary embodiments.

For ease of explanation in describing the relationship of one element or feature to another element(s) or feature(s) as illustrated in the drawings, spatially relative terms such as “beneath”, “below”, “lower”, “above”, and “upper” may be used herein. It will be understood that spatially relative positions are intended to encompass different directions of the device in use or operation in addition to the direction depicted in the drawings. For example, if the device in the drawings is turned over, any element described as being “below” or “beneath” another element would then be oriented “above” or “over” another element. Therefore, the term “below” may encompass both upward and downward directions. The terminology used herein is for the purpose of describing embodiments of the present disclosure and is not intended to limit the present disclosure.

The type of secondary battery includes a coin type, a cylindrical type, a prismatic type, and a pouch type. Prior to a description of embodiments of the present disclosure, first, cylindrical and prismatic secondary batteries are roughly described because the present disclosure may be basically applied to the cylindrical and prismatic secondary batteries.

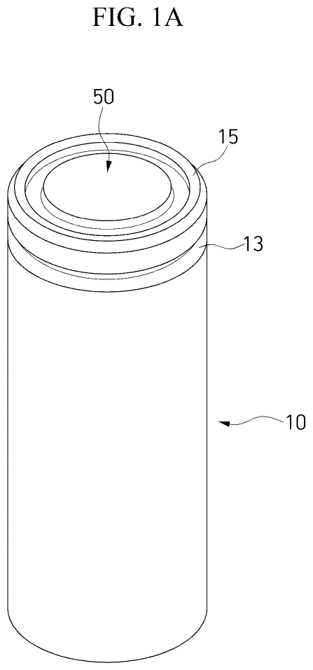

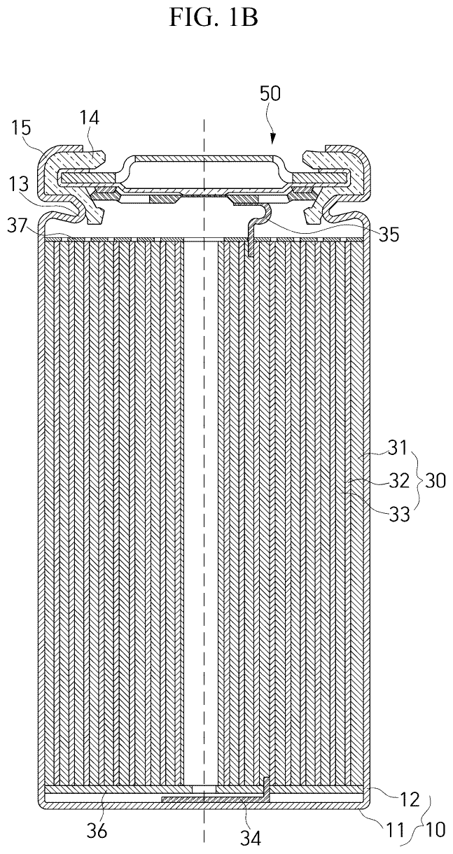

FIG. 1A is an upper perspective view of a cylindrical secondary battery. FIG. 1B is a cross-sectional view of the cylindrical secondary battery.

Referring to FIG. 1A and FIG. 1B, the cylindrical secondary battery may include an electrode assembly 30, a case 10 that accommodates the electrode assembly 30 and an electrolyte therein, a cap assembly 50 that is connected to an opening of the case 10 and that seals the case 10, and an insulating plate 37 disposed between the electrode assembly 30 and the cap assembly 50 within the case 10.

The electrode assembly 30 may include a separator 32 and a first electrode 33 and the second electrode 31 with the separator 32 interposed between, and may be wound in a jelly-roll form.

The first electrode 33 may include a first base and a first active material layer disposed in the first base. A first lead tap 35 may be extended from a first uncoated part that belongs to the first base and in which the first active material layer is not disposed to the outside. The first lead tap 35 may be electrically connected to the cap assembly 50.

The second electrode 31 may include a second base and a second active material layer disposed in the second base. A second lead tap 34 may be extended from a second uncoated part that belongs to the second base and in which the second active material layer is not disposed to the outside. The second lead tap 34 may be electrically connected to the case 10. The first lead tap 35 and the second lead tap 34may be extended in opposite directions.

The first electrode 33 may function as a positive electrode. In this circumstance, the first base may be composed of aluminum foil, for example. The first active material layer may include transition metal oxide, for example. The second electrode 31 may function as a negative electrode. In this circumstance, the second base may be composed of copper foil or nickel foil, for example. The second active material layer may include graphite, for example.

The separator 32 functions to permit a movement of lithium ions and to prevent the short-circuit of the first electrode 33 and the second electrode 31. The separator 32 may be composed of a polyethylene film, a polypropylene film, or a polyethylene-polypropylene film, for example. The case 10 may accommodate the electrode assembly 30 and an electrolyte, and forms an external form of the battery along with the cap assembly 50.

The case 10 may include a body part 12 having an approximate cylindrical shape and a bottom part 11 connected to one side of the body part 12. A beading part 13 that has been deformed toward the inside of the body part 12 may be disposed in the body part 12. A crimping part 15 that has been bent toward the inside of the body part 12 may be disposed at an end of the body part 12 on the opening side.

The beading part 13 may suppress a movement of the electrode assembly 30 within the case 10, and may facilitate the settlement of a gasket 14 and the cap assembly 50. The crimping part 15 may firmly fix the cap assembly 50 by pressurizing an edge of the cap assembly 50 through the gasket 14. The case 10 may be made of iron plated with nickel, for example.

The cap assembly 50 may seal the case 10 by being fixed to the inside of the crimping part 15 through the gasket 14. The cap assembly 50 may include a cap-up part, a safety vent, a cap-down part, an insulating member, and a sub-plate, but the present disclosure is not limited to such examples. The cap assembly 50 may be variously deformed.

The cap-up part may be disposed at the top of the cap assembly 50. The cap-up part may include a terminal part that upward convexly protrudes and that is connected to an external circuit. An output for discharging a gas around the terminal part may be disposed in the cap-up part.

The safety vent may be disposed under the cap-up part. The safety vent may include a protruding part that downward convexly protrudes and that is connected to the sub-plate, and at least one notch disposed around the protruding part. When a gas is generated due to over-charging or an abnormal operation of the secondary battery, the protruding part may be upward deformed by the pressure of the gas and separated from the sub-plate. Furthermore, the safety vent may be cut along the notch. The cut safety vent can prevent the explosion of the secondary battery by discharging the gas to the outside.

The cap-down part may be disposed under the safety vent. A first opening for exposing the protruding part of the safety vent and a second opening for discharging a gas may be disposed in the cap-down part. The insulating member may be disposed between the safety vent and the cap-down part, and may insulate the safety vent and the cap-down part. The sub-plate may be disposed under the cap-down part. The sub-plate may be fixed to the bottom of the cap-down part in order to close the first opening of the cap-down part. The protruding part of the safety vent may be fixed to the sub-plate. The first lead tap 35 that has been withdrawn from the electrode assembly 30 may be fixed to the sub-plate. Accordingly, the cap-up part, the safety vent, the cap-down part, and the sub-plate may be electrically connected to the first electrode 33 of the electrode assembly 30.

The insulating plate 37 may be disposed to adjoin the electrode assembly 30 under the beading part 13. A tap opening for withdrawing the first lead tap 35 may be provided in the insulating plate 37. The cap assembly 50 that has been electrically connected to the first electrode 33 by the first lead tap 35 may face the electrode assembly 30 with the insulating plate 37 interposed therebetween. The cap assembly 50 may maintain the state in which the cap assembly 50 has been insulated from the electrode assembly 30 by the insulating plate 37. The cylindrical secondary battery may include another insulating plate 36 for insulation between the electrode assembly 30 and the bottom part 11 of the case 10.

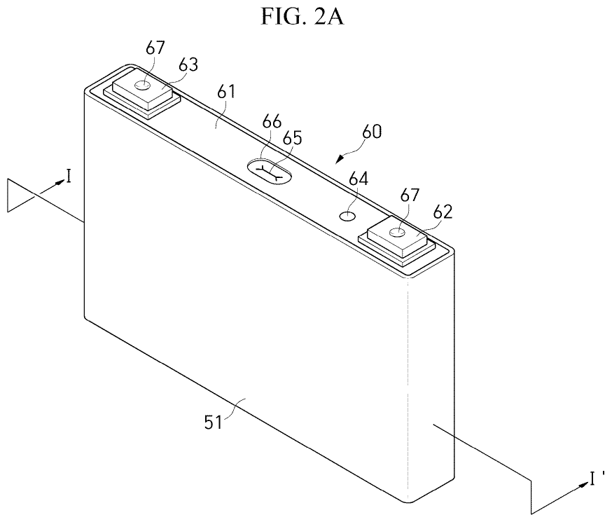

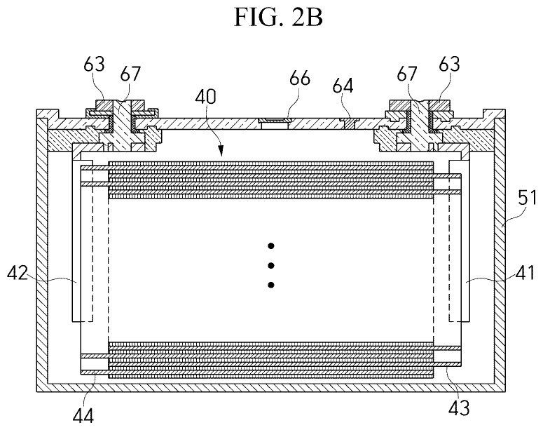

FIG. 2A is a top perspective view of a prismatic secondary battery. FIG. 2B is a cross-sectional view taken along the line I-I′ of FIG. 2A.

First, the external appearance of the prismatic secondary battery illustrated in FIG. 2A will be described.

A case 51 defines an overall appearance of the prismatic secondary battery, and may be made of a conductive metal, such as aluminum, aluminum alloy, or nickel-plated steel. In addition, the case 51 may provide a space for accommodating an electrode assembly therein.

A cap assembly 60 may include a cap plate 61 that covers the opening of the case 51. In some examples, the case 51 and the cap plate 61 may be made of a conductive material. Here, a first terminal 63 and a second terminal 62 may be electrically connected to respective positive and negative (or negative and positive) electrodes inside the case, and may be installed to protrude outward through the cap plate 61.

The cap plate 61 may be equipped with an electrolyte injection port 64 formed to install a sealing plug (or seal pin), and a vent 66 formed with a notch 65. The vent 66 is for discharging gas generated inside the secondary battery. With reference to FIG. 2B, the internal structure of the prismatic secondary battery and the coupling structure with the cap assembly 60 will be further described.

As shown in FIG. 2B, a prismatic secondary battery may include an electrode assembly 40, a first current collector 41, a first terminal 62, a second current collector 42, a second terminal 63, a case 51, and a cap assembly 60.

An electrode assembly 40 may be formed by winding or stacking a stack of a first electrode plate, a separator, and a second electrode plate, which are formed as thin plates or films. When the electrode assembly 40 is a wound stack, a winding axis may be parallel to the longitudinal direction (e.g., the y direction) of the case 51. In some other embodiments, the electrode assembly 40 is a stack type rather than a winding type, and the shape of the electrode assembly 40 is not limited in the present disclosure. In addition, the electrode assembly 40 may be a Z-stack electrode assembly in which a positive electrode plate and a negative electrode plate are inserted into both sides of a separator, which is then bent into a Z-stack. In addition, one or more electrode assemblies may be stacked such that long sides of the electrode assemblies are adjacent to each other and accommodated in the case, and the number of electrode assemblies in the case is not limited in the present disclosure. The first electrode plate of the electrode assembly may act as a negative electrode, and the second electrode plate may act as a positive electrode. Of course, the reverse is also possible.

The first electrode plate may be formed by applying a first electrode active material, such as graphite, carbon, or the like, to a first electrode current collector formed of a metal foil, such as copper, a copper alloy, nickel, a nickel alloy, or the like. The first electrode plate may include a first electrode tab 43 (e.g., a first uncoated portion) that is a region to which the first electrode active material is not applied. The first electrode tab 43 may act as a current flow path between the first electrode plate and the first current collector 41. In some embodiments, when the first electrode plate is manufactured, the first electrode tab 43 is formed by being cut in advance to protrude to one side of the electrode assembly 40, or the first electrode tab 43 protrudes to one side of the electrode assembly 40 more than (e.g., farther than or beyond) the separator without being separately cut.

The second electrode plate may be formed by applying a second electrode active material, such as a transition metal oxide, on a second electrode current collector formed of a metal foil, such as aluminum or an aluminum alloy. The second electrode plate may include a second electrode tab 44 (e.g., a second uncoated portion) that is a region to which the second electrode active material is not applied. The second electrode tab 44 may act as a current flow path between the second electrode plate and the second current collector 42.

In some embodiments, the second electrode tab 44 may be formed by being cut in advance to protrude to the other side (e.g., the opposite side) of the electrode assembly when the second electrode plate is manufactured, or the second electrode plate may protrude to the other side of the electrode assembly more than (e.g., farther than or beyond) the separator without being separately cut.

In some embodiments, the first electrode tab 43 is located on the left side of the electrode assembly 40, and the second electrode tab 44 may be located on the right side of the electrode assembly 40. In some other embodiments, the first electrode tab 43 and the second electrode tab 44 are located on one side of the electrode assembly 40 in the same direction. Here, for convenience of description, the left and right sides are defined according to the secondary battery as oriented in FIG. 1, and the positions thereof may change when the secondary battery is rotated left and right or up and down.

The separator prevents or substantially reduces instances of a short circuit between the first electrode and the second electrode while movement allowing of lithium ions therebetween. The separator may be made of, for example, a polyethylene film, a polypropylene film, a polyethylene-polypropylene film, or the like.

The first electrode tab 43 of the first electrode plate and the second electrode tab 44 of the second electrode plate may be positioned at both ends (e.g., opposite ends) of the electrode assembly 40. In some embodiments, the electrode assembly 40 is accommodated in the case 10 along with an electrolyte.

In addition, in the electrode assembly 40, the first current collector 41 and the second current collector 42 may be welded and connected to the first electrode tab 43 of the first electrode plate and the second electrode tab 44 of the second electrode plate exposed on both sides, respectively, to then be positioned thereat, respectively.

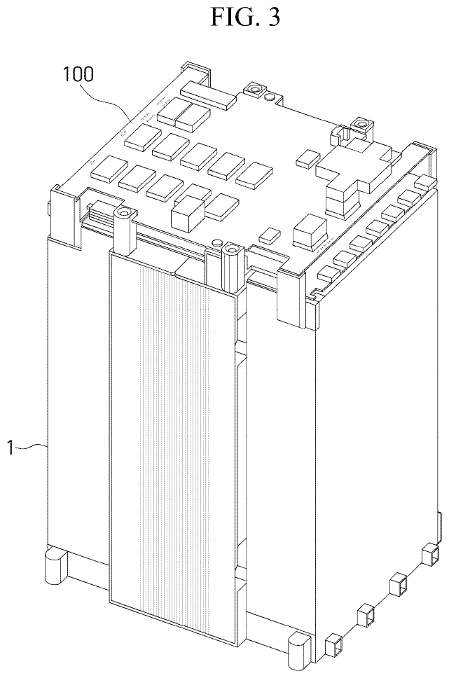

The first current collection part 41 and the second current collection part 42 may be connected to the first terminal 62 and the second terminal 63 described with reference to FIG. 2A, through terminal pins 67, respectively. In some embodiments, outer circumference surfaces of the terminal pins 67 may be subjected to screw processing, and may be fastened to the first terminal 62 and the second terminal 63, respectively, through screw coupling. However, the present disclosure is not limited to such an example, and the terminal pins 67 may be connected to the first terminal 62 and the second terminal 63 in a riveting way or by welding. FIG. 3 is a perspective view of a battery pack including a printed circuit board according to embodiments of the present disclosure.

Referring to FIG. 3, a battery pack according to embodiments of the present disclosure may include a plurality of battery cells (not illustrated), a case 1, and a printed circuit board 100.

The plurality of battery cells may each be the cylindrical secondary battery or the prismatic secondary battery that has been described with reference to FIGS. 1A to 2B as examples.

The case 1 may have the plurality of battery cells mounted thereon, and may function to fix the mounted battery cells so that the mounted battery cells are not shook therein and to protect the mounted battery cells therein against vibration or an impact.

The printed circuit board 100 may include a battery management system (BMS), and may be connected to the plurality of battery cells and the case 1. Hereinafter, the printed circuit board according to embodiments of the present disclosure is described with reference to the accompanying drawings.

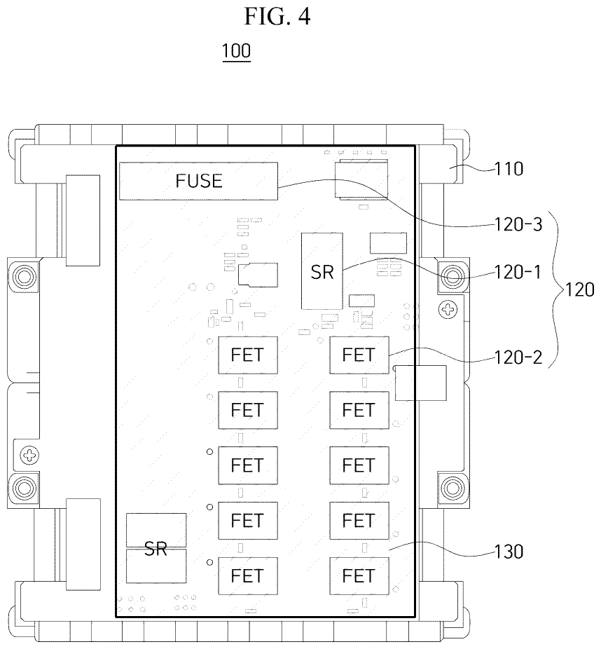

FIG. 4 is a plan view of the printed circuit board according to embodiments of the present disclosure.

Referring to FIG. 4, the printed circuit board according to embodiments of the present disclosure 100 may include a substrate 110, a large current stage part 120, and a coating layer 130.

The substrate 110 consists of a mounting area in which various elements that constitute the BMS are mounted and a wiring area in which the elements are connected. In embodiments, the substrate 110 may be constructed by overlapping fiber glass and the prepreg (PP) of an epoxy plastic combination in multiple layers as an insulator. The large current stage part 120 may be some of the various elements that constitute the BMS, and may be disposed in the mounting area of the substrate 110. In embodiments, the large current stage part 120 may include one or more of an SR latch 120-1, a field effect transistor (FET) 120-2, and a fuse 120-3. The large current stage part 120 is a part into which a current directly flows, and heat may be generated from the large current stage part. Accordingly, it is important for the large current stage part 120 to effectively discharge heat.

The coating layer 130 may include phase change materials (PCMs) that cover the large current stage part 120. The PCMs refers to material which can accumulate or discharge a large amount of thermal energy without causing a temperature change in a process of the phase of the PCMs being changed from solid to liquid, from liquid to gas, or vice versa at a specific temperature. That is, a temperature rise of the PCMs is delayed because the PCMs absorbs heat without further causing a temperature change in a temperature section in which a phase change occurs. The coating layer 130 may have a heat dissipation function so that heat can exit by covering heating parts, such as the SR latch 120-1, FET 120-2, and the fuse 120-3. Furthermore, in embodiments, the coating layer 130 may be formed to cover all of a plurality of vias through which the layer of the substrate 110 passes.

In embodiments, the coating layer 130 may be formed by coating a coating solution including the PCMs and silicon. Furthermore, the PCMs may include capsulated paraffin wax. The PCMs is a relatively more expensive material than silicon. Accordingly, if the coating layer 130 is used, costs can be reduced compared to a circumstance in which only the PCMs is used because the coating solution is manufactured by mixing silicon with a capsulated PCMs potting agent. Referring to Table 1, when comparing a circumstance in which the PCMs is not used and a circumstance in which the PCMs and silicon are mixed and coated on the substrate, it may be seen that a temperature of 20° C. or higher is reduced in the circumstance in which the PCMs and silicon are mixed and coated on the substrate.

TABLE 1

| SAMPLE | TYPE | PCMS RATIO | MAX TEMPERATURE |
|---|---|---|---|
| No PCMs | — | | 114.28 |
| Silicon PCMs | Silicon | 20~25 | 103.6 |
| Silicon PCMs | Silicon | 30~40 | 94.63 |

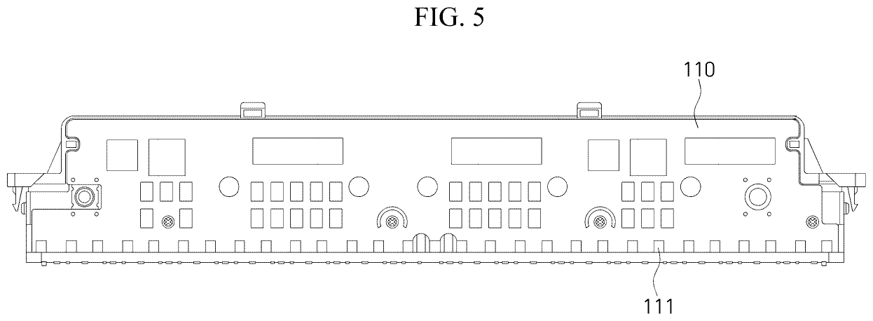

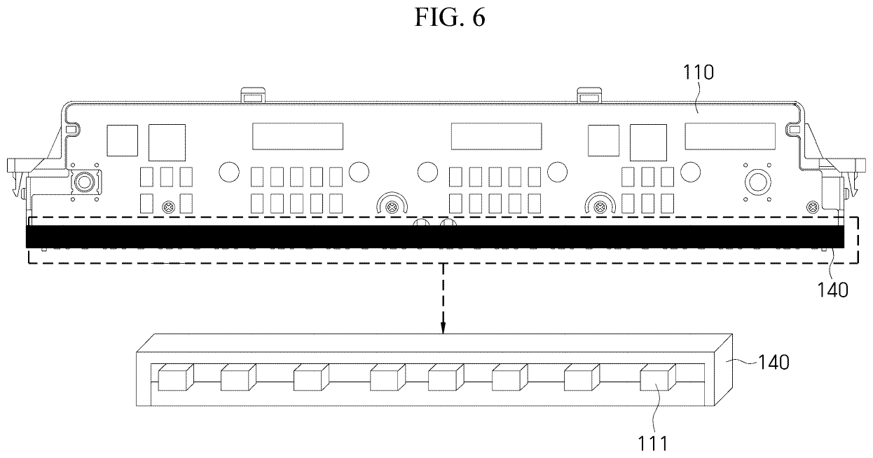

In embodiments, the coating layer 130 may have a thickness of 1 cm to 1.5 cm. When the coating layer 130 is less than 1 cm, the waterproof function is reduced. When the coating layer 130 is more than 1.5 cm, a heat dissipation effect is reduced because the coating layer 130 is too thick and heat of the large current stage part 120 is not discharged. According to embodiments of the present disclosure, a waterproof effect can be achieved and heat that is generated from a heating part can be effectively discharged because the coating layer 130 including the PCMs is formed. According to embodiments of the present disclosure, the printed circuit board 100 can be cooled and the size of the printed circuit board 100 can be minimized by generally covering a heating part without the need to open a part of the heating part because the coating layer 130 including the PCMs is generally formed on the printed circuit board 100. According to embodiments of the present disclosure, costs can be reduced compared to a circumstance in which only the PCMs is used because the coating solution is manufactured by mixing silicon with the capsulated PCMs potting agent. In embodiments, the coating layer 130 may be formed to not cover a metal tab 111 that is formed in a part of the outskirts of the substrate 110. Hereinafter, the coating layer 130 that is formed to not cover the metal tab 111 is described with reference to FIGS. 5 and 6.

FIG. 5 is a diagram illustrating a form before a guide bar is applied to the printed circuit board according to embodiments of the present disclosure.

Referring to FIG. 5, the coating layer 130 may be formed to not cover the metal tab 111 that is formed in a part of the outskirts of the substrate 110. If the coating solution that forms the coating layer 130 flows into the outskirts of the substrate 110, the coating solution may affect performance of a battery cell because the coating solution flows to an upper part of the plurality of battery cells or the case 1. Accordingly, the coating layer 130 may be formed to not cover the metal tab 111 that is formed in a part of the outskirts of the substrate 110 so that the coating solution does not flow into the outskirts of the substrate 110.

FIG. 6 is a diagram illustrating a form after the guide bar is applied to the printed circuit board according to embodiments of the present disclosure.

Referring to FIG. 6, the coating layer 130 may be formed so that the coating solution that forms the coating layer 130 does not flow into the metal tab 111 by covering the outskirts of the substrate 110 including the metal tab 111 with a guide bar 140. When the outskirts of the substrate 110 is covered with the guide bar 140, the coating solution that forms the coating layer 130 can be prevented from flowing up to the metal tab 111 by the guide bar 140, and may be hardened in this state. Accordingly, the coating solution can be prevented from flowing into the outskirts of the substrate 110.

According to embodiments of the present disclosure, it is possible to prevent the coating solution from flowing into the outskirts of the substrate 110 because the coating layer 130 is formed by covering the outskirts of the substrate 110 with the guide bar 140.

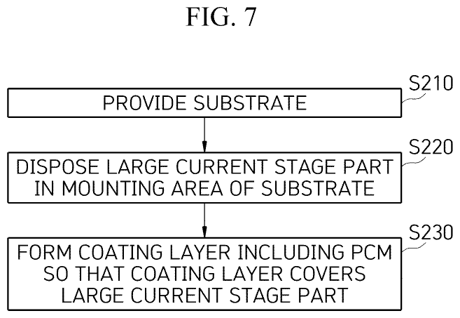

FIG. 7 is a flowchart for describing a method of manufacturing a printed circuit board according to embodiments of the present disclosure.

As illustrated in FIG. 7, the method of manufacturing a printed circuit board according to embodiments of the present disclosure may include step S210 to step S230.
Step S210 may be a step of providing the substrate.
Step S220 may be a step of disposing the large current stage part in the mounting area of the substrate. In embodiments, step S220 may include a step of disposing the large current stage part, including one or more of the SR latch, the FET, and the fuse, in the mounting area of the substrate.
Step S230 may be a step of forming the coating layer including the PCMs so that the coating layer covers the large current stage part. In embodiments, step S230 may include a step of forming the coating layer by coating the coating solution including the PCMs and silicon. In another embodiment, step S230 may include a step of forming the coating layer so that the coating layer has a thickness of 1 cm to 1.5 cm. In another embodiment, step S230 may include a step of forming the coating layer so that the coating layer does not cover the metal tab that is formed in a part of the outskirts of the substrate.

As described above, the step of forming the coating layer so that the coating layer does not cover the metal tab may include a step of covering the outskirts of the substrate including the metal tab with the guide bar, a step of flowing the coating solution on the substrate so that the coating solution that forms the coating layer does not flow into the metal tab, a step of forming the coating layer by hardening the coating solution, and a step of removing the guide bar. The method of manufacturing a printed circuit board according to embodiments of the present disclosure has been described with reference to the flowcharts presented in the drawings. For a simple description, the method has been illustrated and described as a series of blocks, but the present disclosure is not limited to the sequence of the blocks, and some blocks may be performed in a sequence different from or simultaneously with that of other blocks, which has been illustrated and described in this specification. Various other branches, flow paths, and sequences of blocks which achieve the same or similar results may be implemented. Furthermore, all the blocks illustrated in order to implement the method described in this specification may not be required.

In the description given with reference to FIG. 7, each of the steps may be further divided into additional steps or the steps may be combined into smaller steps depending on an implementation example of the present disclosure. Furthermore, some of the steps may be omitted, if necessary, and the sequence of the steps may be changed. Furthermore, the contents of FIGS. 1A to 6, although some contents are omitted from the contents of FIGS. 1A to 6, may be applied to the contents of FIG. 7. Furthermore, the contents of FIG. 7 may be applied to the contents of FIGS. 1A to 6.

Hereinafter, materials which may be used in a secondary battery according to an embodiment of the present disclosure are described.

A compound (e.g., a lithiated intercalation compound) capable of reversible intercalation and deintercalation of lithium may be used as a positive electrode active material. Specifically, one type or more selected among complex oxides of metal, selected among cobalt, manganese, nickel, and a combination of them, and lithium may be used as the positive electrode active material.

The complex oxide may be lithium transition metal complex oxide. A detailed example of the complex oxide may include lithium nickel-based oxide, lithium cobalt-based oxide, lithium manganese-based oxide, a lithium ferrous phosphate-based compound, cobalt-free nickel-manganese-based oxide, or a combination of them.

For example, a compound that is represented as one of the following chemical formulas may be used. LiₐA_{1-b}X_{b}O_{2-c}D_{c} (0.90≤a≤1.8, 0≤b≤0.5, 0≤c≤0.05); LiₐMn_{2-b}X_{b}O_{4-c}D_{c} (0.90≤a≤1.8, 0≤b≤0.5, 0≤c≤0.05); LiₐNi_{1-b-c}CO_{b}X_{c}O_{2-α}D_{α} (0.90≤a≤1.8, 0≤b≤0.5, 0≤c≤0.5, 0≤α≤2); LiₐNi_{1-b-c}Mn_{b}X_{c}O_{2-α}D_{α} (0.90≤a≤1.8, 0≤b≤0.5, O≤c≤0.5, 0≤α≤2); LiₐNi_{b}Co_{c}L_{d}¹GₑO₂ (0.90≤a≤1.8, 0≤b≤0.9, O≤c≤0.5, 0≤d≤0.5, 0≤e≤0.1); LiₐNiG_{b}O₂ (0.90≤a≤1.8, 0.001≤b≤0.1); LiₐCoG_{b}O₂ (0.90≤a≤1.8, 0.001≤b≤0.1); LiₐMn_{1-b}G_{b}O₂ (0.90≤a≤1.8, 0.001≤b≤0.1); LiaMn2Gb04 (0.90≤a≤1.8, 0.001≤b≤0.1); LiₐMn_{1-g}G_{g}PO₄ (0.90≤a≤1.8, 0≤g≤0.5); Li_{(3-f)} Fe₂(PO₄)₃(0≤f≤2); and LiₐFePO₄ (0.90≤a≤1.8).

In the chemical formula, A may be Ni, Co, Mn, or a combination of them. X may be Al, Ni, Co, Mn, Cr, Fe, Mg, Sr, V, a rare earth element, or a combination of them; D may be O, F, S, P, or a combination of them. G may be Al, Cr, Mn, Fe, Mg, La, Ce, Sr, V, or a combination of them. LI may be Mn, Al, or a combination of them.

A positive electrode for a lithium secondary battery may include a current collector and a positive electrode active material layer formed on the current collector. The positive electrode active material layer may include the positive electrode active material, and may further include a binder and/or a conductive material.

Content of the positive electrode active material may be 90 wt. % to 99.5 wt. % with respect to the positive electrode active material layer 100 wt. %. Content of the binder and the conductive material may be 0.5 wt. % to 5 wt. % with respect to the positive electrode active material layer 100 wt. %. Al may be used as the current collector, but the present disclosure may not be limited thereto.

A negative electrode active material may include a material capable of reversibly Intercalation/de-intercalation with respect to lithium ions, lithium metal, an alloy of lithium metal, a material capable of doping and dedoping with respect to lithium, or transition metal oxide.

The material capable of reversibly Intercalation/de-intercalation with respect to lithium ions may include a carbon-based negative electrode active material, for example, crystalline carbon, amorphous carbon, or a combination of them. An example of the crystalline carbon may include graphite, such as natural graphite or synthetic graphite. Examples of the amorphous carbon may include soft or hard carbon, mesophase pitch carbide, and fired coke.

An Si-based negative electrode active material or an Sn-based negative electrode active material may be used as the material capable of doping and dedoping with respect to lithium. The Si-based negative electrode active material may be silicon, a silicon-carbon composite, SiOₓ (0<x<2), a Si-based alloy, or a combination of them.

The silicon-carbon composite may be a composite of silicon and amorphous carbon. According to an implementation example, the silicon-carbon composite may include silicon particles, and may have a form in which amorphous carbon has been coated on surfaces of silicon particles.

The silicon-carbon composite may further include crystalline carbon. For example, the silicon-carbon composite may include a core including crystalline carbon and silicon particles, and an amorphous carbon coating layer disposed on a surface of the core.

A negative electrode for a lithium secondary battery may include a current collector and a negative electrode active material layer disposed on the current collector. The negative electrode active material layer may include the negative electrode active material, and may further include a binder and/or a conductive material.

For example the negative electrode active material layer may include the negative electrode active material of 90 wt. % to 99 wt. %, the binder of 0.5 wt. % to 5 wt. %, and the conductive material of 0 wt. % to 5 wt. %.

A nonaqueous-based binder, an aqueous-based binder, a dry binder, or a combination of them may be used as the binder. If the aqueous-based binder is used as a binder for the negative electrode, the binder for the negative electrode may further include a cellulose-series compound capable of assigning viscosity.

One selected among nickel foil, stainless steel foil, titanium foil, nickel foam, copper foam, a polymer base on which a conductive metal has been coated, and a combination of them may be used as a current collector for the negative electrode.

An electrolyte for a lithium secondary battery may include a nonaqueous organic solvent and lithium salts.

The nonaqueous organic solvent may play a role as a medium through which ions that are involved in an electrochemical reaction of a battery can move.

The nonaqueous organic solvent may be a carbonate-based, ester-based, ether-based, ketone-based, or alcohol-based solvent, an aprotic solvent, or a combination of them. The carbonate-based, ester-based, ether-based, ketone-based, or alcohol-based solvent, or the aprotic solvent may be used solely, or two types or more of them may be mixed and used as the nonaqueous organic solvent.

Furthermore, if the carbonate-based solvent is used, annular carbonate and chain carbonate may be mixed and used.

A separator may be present between the positive electrode and the negative electrode depending on the type of lithium polypropylene, secondary battery. Polyethylene, and polyvinylidene fluoride, or a multi-layer having two or more layers of them may be used as the separator.

The separator may include a porous base, and a coating layer including an organic matter, an inorganic matter, or a combination of them that is disposed on one or both sides of the porous base.

The organic matter may include a polyvinylidene fluoride-based heavy antibody or (meth)acrylic polymer.

The inorganic matter may include inorganic particles selected among Al₂O₃, SiO₂, TiO₃, SnO₂, CeO₂, MgO, NiO, Cao, GaO, Zno, ZrO₂, Y₂O₃, SrTiO₃, BaTiO₃, Mg(OH)₂, boehmite, and a combination of them, but the present disclosure is not limited thereto.

The organic matter and the inorganic matter may have a form in which the organic matter and the inorganic matter have been mixed in one coating layer or a form in which a coating layer including the organic matter and a coating layer including the inorganic matter have been stacked

Although the present disclosure has been described above in connection with the limited embodiments and drawings, the present disclosure is not limited to the embodiments. A person having ordinary knowledge in the art to which the present disclosure pertains may modify and change the present disclosure within the technical spirit of the present disclosure and the equivalent range of the following claims.

### DESCRIPTION OF REFERENCE NUMERALS

100: printed circuit board 110: substrate
111: metal tab 120: large current stage part
130: coating layer

What is claimed is:

1. A printed circuit board comprising:
a substrate;
a large current stage part disposed in a mounting area of the substrate; and
a coating layer comprising phase change materials (PCMs) and covering the large current stage part.

2. The printed circuit board as claimed in claim 1, wherein the large current stage part comprises one or more of an SR latch, a field effect transistor (FET), and a fuse.

3. The printed circuit board as claimed in claim 1, wherein the coating layer is formed by coating with a coating solution comprising the PCMs and silicon.

4. The printed circuit board as claimed in claim 3, wherein the PCMs comprise capsulated paraffin wax.

5. The printed circuit board as claimed in claim 1, wherein the coating layer has a thickness of 1 cm to 1.5 cm.

6. The printed circuit board as claimed in claim 1, wherein the coating layer is formed not to cover a metal tab formed in a part of outskirts of the substrate.

7. The printed circuit board as claimed in claim 6, wherein the coating layer is formed so that the coating solution that forms the coating layer does not flow into the metal tab by covering with a guide bar the outskirts of the substrate comprising the metal tab.

8. A battery pack comprising:
a plurality of battery cells;
a case on which the plurality of battery cells is mounted; and
a printed circuit board connected to the plurality of battery cells and the case,
wherein the printed circuit board comprises a substrate, a large current stage part disposed in a mounting area of the substrate, and a coating layer that covers the large current stage part.

9. The battery pack as claimed in claim 8, wherein the large current stage part comprises one or more of an SR latch, a field effect transistor (FET), and a fuse.

10. The battery pack as claimed in claim 8, wherein the coating layer is formed by coating with a coating solution comprising the PCMs and silicon.

11. The battery pack as claimed in claim 10, wherein the PCMs comprise capsulated paraffin wax.

12. The battery pack as claimed in claim 8, wherein the coating layer has a thickness of 1 cm to 1.5 cm.

13. The battery pack as claimed in claim 8, wherein the coating layer is formed not to cover a metal tab formed in a part of outskirts of the substrate.

14. The battery pack as claimed in claim 13, wherein the coating layer is formed so that the coating solution that forms the coating layer does not flow into the metal tab by covering with a guide bar the outskirts of the substrate comprising the metal tab.

15. A method of manufacturing a printed circuit board, comprising:
providing a substrate;
disposing a large current stage part in a mounting area of the substrate; and
forming a coating layer comprising phase change materials (PCMs) so that the coating layer covers the large current stage part.

16. The method as claimed in claim 15, wherein the disposing of the large current stage part comprises disposing the large current stage part comprising one or more of an SR latch, a field effect transistor (FET), and a fuse in the mounting area of the substrate.

17. The method as claimed in claim 15, wherein the forming of the coating layer comprises forming the coating layer by coating with a coating solution comprising the PCMs and silicon.

18. The method as claimed in claim 15, wherein the forming of the coating layer comprises forming the coating layer so that the coating layer has a thickness of 1 cm to 1.5 cm.

19. The method as claimed in claim 15, wherein the forming of the coating layer comprises forming the coating layer so that the coating layer does not cover a metal tab formed in a part of outskirts of the substrate.

20. The method as claimed in claim 19, wherein the forming of the coating layer so that the coating layer does not cover the metal tab comprises:
covering with a guide bar the outskirts of the substrate comprising the metal tab;
flowing a coating solution that forms the coating layer on the substrate so that the coating solution does not flow into the metal tab;
forming the coating layer by hardening the coating solution; and
removing the guide bar.
